(19) United States
(12) Patent Application Publication
(10) Pub. No.: US 2008/0157210 A1
(43) Pub. Date: Jul. 3, 2008

(54) High-linearity and high-power CMOS structure and manufacturing method for the same

(75) Inventors: Hsien-Chin Chiu, Taipei City (TW); Chien-Cheng Wei, Taipei City (TW); Wei-Hsien Lee, Sinjhuang City (TW); Wu-Shiung Feng, Taipei City (TW)

Correspondence Address: NIKOLAI & MERSEREAU, P.A., 900 SECOND AVENUE SOUTH, SUITE 820, MINNEAPOLIS, MN, 55402, US

(73) Assignee: Chang Gung University, Kwei-Shan (TW)

(21) Appl. No.: 11/645,915

(22) Filed: Dec. 27, 2006

(51) Int. Cl. H01L 29/94

(52) U.S. Cl. 257/369

(57) ABSTRACT

This invention relates to a high-linearity and high-power CMOS structure and a method for the same and particularly to a field plate technology that is applied to a CMOS component, in which the field plate is formed on a dielectric layer of the CMOS, being arranged above a gate and a drain. An electric field is provided to significantly improve the RF linearity and output power of the CMOS component.

### BACKGROUND OF THE INVENTION

1. Field of the Invention

This invention relates to a high-linearity and high-power CMOS structure and a method for the same and particularly to a field plate technology that is applied to a CMOS component and is formed on a dielectric layer above a gate and a drain.

2. Description of Related Art

With reference to FIG. 1, a conventional CMOS component comprises a Si bulk as a base 100 on which a gate 101 is arranged, in which a source 103 and a drain 102 are arranged in the base 100 between the two sides of the gate 101. Besides, a gate dielectric layer is arranged between the gate 101 and the base 100, and may be made of silica and serve as an insulation layer that provides the CMOS component with an extremely high input resistance.

Further, metallic silicide layers 109 are provided above the source 103, the drain 102, and the gate 101 to reduce the resistances of source 103, drain 102, and gate 101.

Next, the dielectric layer 104 is made to cover the gate 101, the source 103, and the drain 102. Transistors formed with the gate 101, the source 103, and the drain 102 that are arranged under the dielectric layer are a PMOS transistor and a NMOS transistor, and a gate dielectric layer 107 is provided between the gate 101 and the base 100.

In the existing CMOS component, the Si bulk is used as the base on which the gate is structured, in which the source and the drain are arranged in the base between the two sides of the gate. The CMOS component has been widely used in the advanced RF technology, of which the cost is low, and may be applied to a digital integrated circuit. For the high frequency (HF) component, “linearity and output power” are very important parameters to increase the dynamic range of the CMOS component, in order to satisfy a new generation of communication system. Thus, another technology must be developed to increase the RF linearity and output power of the CMOS component. When carriers of a conventional CMOS component moves, they fall into traps on the surface of the CMOS component so as to make poor the RF linearity and output power of the CMOS component, and the high drain induced barrier lowing (DIBL) also brings a flood of leakage current of the CMOS component and increases DC power consumption of the CMOS component.

Consequently, because of the technical defects of described above, the applicant keeps on carving unflaggingly through wholehearted experience and research to develop the present invention, which can effectively improve the defects described above.

### SUMMARY OF THE INVENTION

It is a problem to be solved that when carriers of a conventional CMOS component moves, they fall into traps on the surface of the CMOS component so as to make poor the RF linearity and output power of the CMOS component, and that the high drain induced barrier lowing (DIBL) also brings a flood of leakage current of the CMOS component and increases DC power consumption of the CMOS component.

In order to solve the problem, it is a main objective of this invention to increase RF linearity and output power and decrease leakage current and DC power consumption. Thus, a field plate technology is proposed and applied to the CMOS component.

The concept of technology traces back to the development of a high-voltage diode applied to a guard ring. Basically, this principle is to improve other areas adjacent to a junction on a conductive plane for a high electric field to exist in.

The conductive plane provides a balanced electric field so as to reduce electric breakdown caused by a peak of the high electric field. In order to turn on a channel of a semiconductor, an electron needs enough energy to bring avalanche ionization, and thus the field plate brings enough attenuation in the gate electric field for the utilization of a high voltage.

The field plate is applied to High Electron Mobility Transistors (HEMTs). It proved in the research that the field plate is applied in the HEMTs, which covers the margin along the gate and the drain, to reduce the electric field and improve the RF linearity and the breakdown voltage.

The field plate has not yet been applied to the CMOS component due to its thick dielectric layer. In a standard 0.35 um and 0.18 un CMOS manufacturing processes, the thickness of dielectric layer is around 10000 and 7500 angstrom, respectively. The field plate technology that applied to the quite thick dielectric layer does not impact on the electric field intensity. A scaling down technology is used in the CMOS component to significantly reduce the thickness of dielectric layer. The scaling-down 0.13 um CMOS manufacturing process is used so that the thickness of dielectric layer is reduced to 4000 angstrom, and thus it has proved to be used in the field plate technology. In the field plate technology for the 0.13 um COMS component, a standard CMOS manufacturing process runs.

For a virtue compared with that of the prior art, in this invention, the RF linearity and output power may be increased, and the leakage current and DC power consumption may be decreased.

### BRIEF DESCRIPTION OF THE DRAWINGS

FIG. 1 is a structural view of a conventional CMOS component;

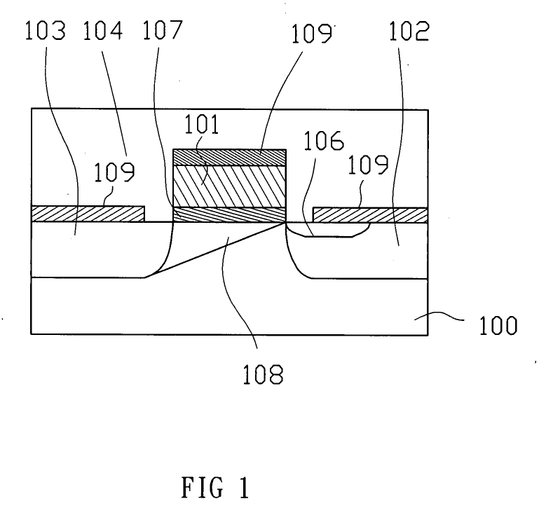

FIG. 2 is a structural view of a CMOS component according to this invention;

FIG. 3A is a graph of the comparison of an I-V curve of the CMOS component according to this invention with that of the conventional CMOS component;

FIG. 3B is a graph of the comparison of leakage current of the CMOS component according to this invention with that of the conventional CMOS component;

FIG. 4 is a graph of the comparison of the input power, high-frequency gain, and output power of conventional CMOS component with those of CMOS component according to this invention; and

FIG. 5 is a graph of the comparison of the 5.8 GH and 5.81 GHz input power and fundamental output power, IIP3, and IM3 of conventional CMOS component with those of CMOS component according to this invention.

### DETAILED DESCRIPTION OF THE PREFERRED EMBODIMENTS

Now, the present invention will be described more specifically with reference to the following embodiments. It is to be noted that the following descriptions of preferred embodiments of this invention are presented herein for purpose of illustration and description only; it is not intended to be exhaustive or to be limited to the precise form disclosed.

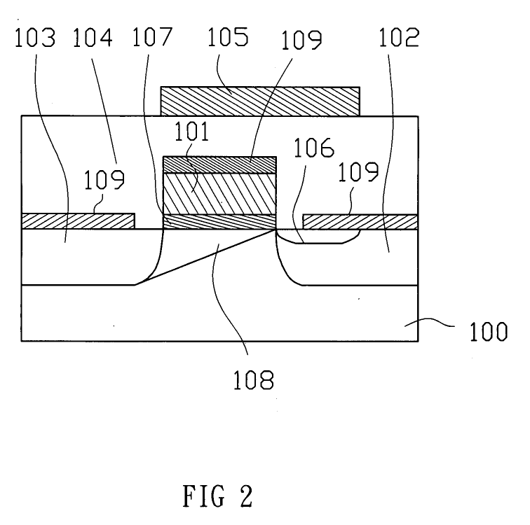

In an embodiment of this invention, a field plate technology is applied to a NMOS component in a standard TSMC 0.13 um CMOS process, in which, as shown in FIG. 2, the CMOS component is structured with a Si bulk as a base 100, comprising a gate 101 on a base 100, in which a source 103 and a drain 102 are arranged in the base 100 between the two sides of the gate 101. Besides, a gate dielectric layer 107 is arranged between the gate 101 and the base 100, and may be made of silica and serve as an insulation layer that provides the CMOS component with an extremely high input resistance.

Further, metallic silicide layers 109 are provided above the source 103, the drain 102, and the gate 101 to reduce the resistances of source 103, drain 102, and gate 101.

Next, a dielectric layer 104 is made to cover the gate 101, the source 103, and the drain 102. Transistors formed with the gate 101, the source 103, and the drain 102 that are arranged under the dielectric layer are a PMOS transistor and a NMOS transistor. The field plate 105 is formed on the dielectric layer 104 and opposite to the top sides of the gate 101 and the drain 102, and a gate dielectric layer 107 is provided between the gate 101 and the base 100.

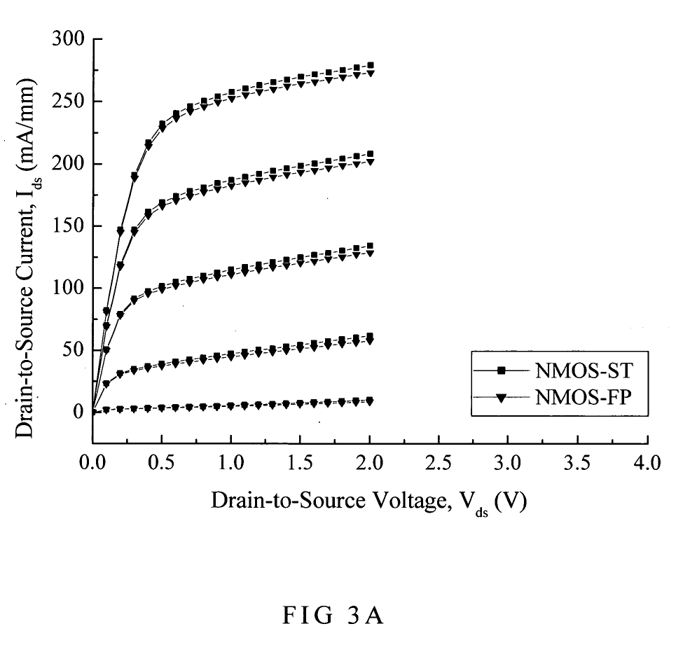

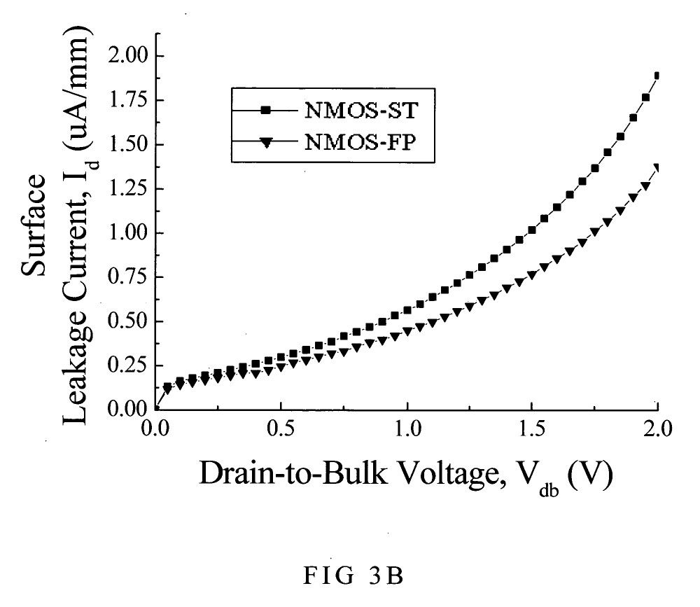

The gate 101 of normally operating CMOS component makes an electric field induce a channel layer 108 in the base 100. An extra electric field provided by the field plate 105 is used to bring attenuation in the gate electric field so as to reduce electric breakdown caused by peaks of high electric field. The field plate 105 brings enough attenuation in the gate electric field for the utilization of a high voltage of the CMOS component and induces a depletion region 106 in the drain 102. In FIG. 3A, NMOS-ST is used as a NMOS component without any field plate. NMOS-FP is a NMOS component provided with a field plate, because the field plate 105 induces the depletion region 106 to lower valid current density, Ids. As shown in FIG. 3B, since NMOS-FP is provided with the low DIBL, the leakage current of the CMOS component is lowered and the DC power consumption is reduced.

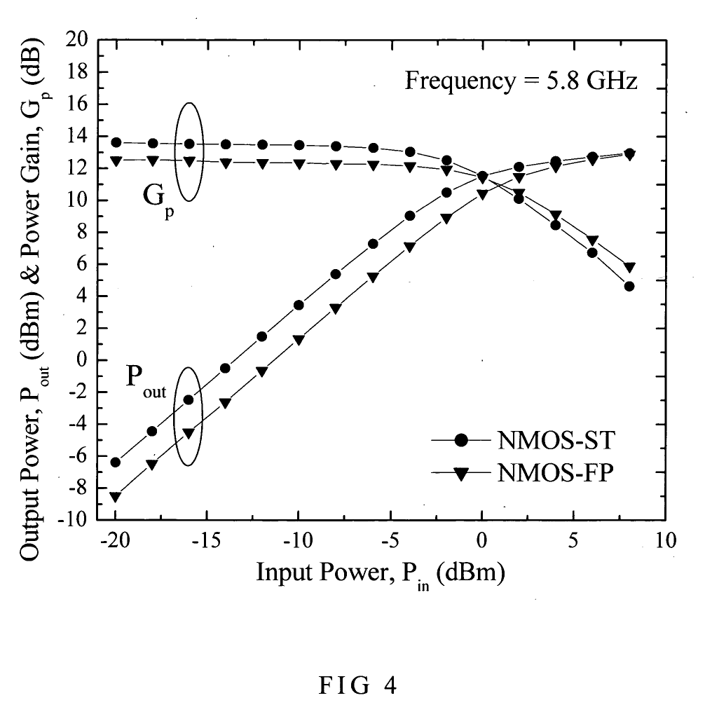

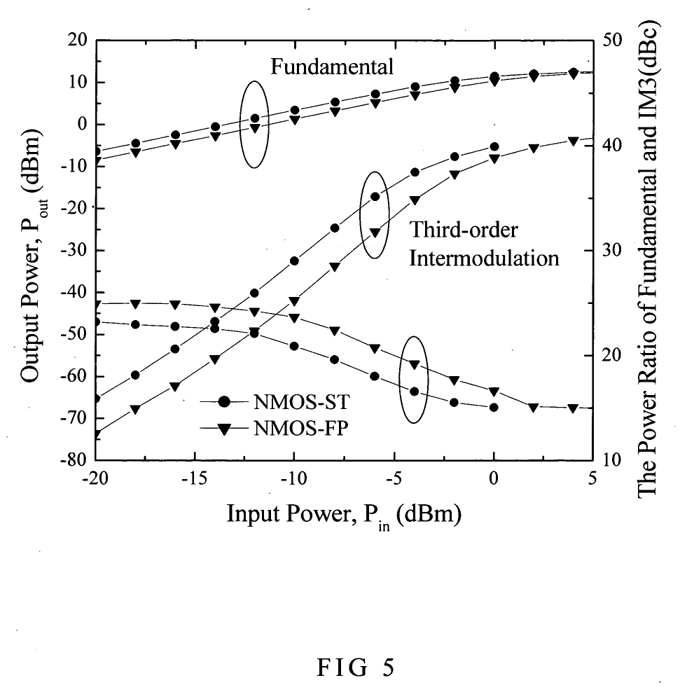

The field plate 105 induces the depletion region 106 to lower the opportunity of carriers falling into traps on the surface of the CMOS component so that better RF linearity is obtained. As shown in FIG. 4, at the state of bias voltage Vds=1.5V and Vg=0.9V, by means of impedance matching and adjustment of a load impedance to maximum output power at the RF of 5.8 GHz, the maximum output power of NMOS-ST is 10.2 dBm, the 1 dBm gain compression point of NMOS-ST is −2 dBm, the maximum output power of NMOS-FP is 10.5 dBm, and the 1 dBm gain compression point of NMOS-FP is 0 dBm. It is apparent that the range of input power of the NMOS-FP is wider than that of the NMOS-ST, so the RF linearity and RF output power of the NMOS-FP are higher, but the power gain of NMOS-FP decreases. In order to again prove the higher linearity of NMOS-FP at RF, as shown in FIG. 5, 5.8 GHz and 5.81 GHz are inputted. In the condition of −10 dBm input power, the ratio of fundamental of NMOS-ST to Third-order Intermodulation (IM3) is −20.9 dBc, while the ratio of fundamental of NMOS-FP to Third-Order Intermodulation (IM3) is −23.7 dBc. The Third-order Intermodulation (IM3) of NMOS-ST is at −32.4 dBm, while the Third-order Intermodulation (IM3) of NMOS-FP is at −41.8 dBm. The Third-Order Intercept point (IIP3) of NMOS-ST is at 2 dBm, while the Third-Order Intercept point (IIP3) of NMOS-FP is at 6 dBm. Known from the description above, the RF linearity of NMOS-FP is higher.

The field plate 105 controls the electric field of normally operating CMOS, it brings enough attenuation in the gate electric field for the utilization of a high voltage, widens the operation range of input voltage, reduces the DC power consumption, and increases the RF output power.

In this invention, the field plate 105 is applied to control the gate electric field and form the depletion region 106 in the drain 102 so that the CMOS component increases the RF linearity and the RF output power. Thus, the field plate technology is not limited to the CMOS component, and other CMOS components that control the gate electric field, bring the depletion region 106 in the drain 102, and increase the RF linearity and RF output power may be applied to this invention.

From the description above, the field plate is provided on the dielectric layer of CMOS component.

The dielectric layer varies with the CMOS manufacturing process, and the thickness of dielectric layer must be less than 4000 angstrom. The dielectric layer is made of an insulation material. The insulation material is a group formed with silicon nitride, silica, silicon oxynitride, and a laminated layer of silicon nitride, silica, and silicon oxynitride.

The field plate is made of a conductive material. The conductive material is metal, metal silicide layer, or polysilicon.

The transistors formed with the gate, the source, and the drain that are arranged under the dielectric layer of conventional CMOS is a PMOS transistor and a NMOS transistor, and the PMOS transistor and the NMOS transistor may be applied to RF.

The field plate is formed on the CMOS component; the field plate controls the gate electric field and forms the depletion region in the drain so that the CMOS component increases the RF linearity and the RF output power. The CMOS component is a conventional CMOS component or a hetero-structural CMOS component. The hetero-structural CMOS component is based on the conventional CMOS component to improve the characteristics of conventional CMOS of which the structure is modified.

A voltage is offered on the field plate, so an extra electric field is formed to attenuate the gate electric field of normally operating CMOS component and reduce electric breakdown caused by peaks of the high electric field, and the field plate brings enough attenuation in the gate electric field for the utilization of high voltage and widens the range of input voltage.

The voltage is offered on the field plate to make the drain induce the depletion region because the field plate induces the depletion region to lower the valid current density, Ids and lower the opportunity of carriers falling into traps on the surface of the CMOS component, and thus the better RF linearity and DIBL are obtained to lower the leakage current of the CMOS component, reduce the DC power consumption, and increase the RF output power.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A high-linearity and high-power CMOS structure, comprising:
a CMOS component;
a field plate formed on the CMOS component; the field plate controlling the gate electric field and forming the depletion region in the drain so that the CMOS component increases the RF linearity and the RF output power.

2. The high-linearity and high-power CMOS structure according to claim 1, wherein the CMOS component is a conventional CMOS component.

3. The high-linearity and high-power CMOS structure according to claim 1, wherein the CMOS component is a hetero-structural CMOS component.

4. The high-linearity and high-power CMOS structure according to claim 1, wherein the field plate is provided on a dielectric layer of the CMOS component.

5. The high-linearity and high-power CMOS structure according to claim 4, wherein the dielectric layer varies with the CMOS manufacturing process and the thickness of dielectric layer must be less than 4000 angstrom.

6. The high-linearity and high-power CMOS structure according to claim 4, wherein the dielectric layer is made of an insulation material.

7. The high-linearity and high-power CMOS structure according to claim 6, wherein the insulation material is a group formed with silicon nitride, silica, silicon oxynitride, and a laminated layer of silicon nitride, silica, and silicon oxynitride.

8. The high-linearity and high-power CMOS structure according to claim 1, wherein the field plate is opposite to the bottom of part of gate or the overall gate.

9. The high-linearity and high-power CMOS structure according to claim 1, wherein the field plate is opposite to the bottom of the partial or overall drain extending from the gate.

10. The high-linearity and high-power CMOS structure according to claim 1, wherein the field plate is made of a conductive material.

11. The high-linearity and high-power CMOS structure according to claim 10, wherein the conductive material is metal, metal silicide layer, or polysilicon.

12. The high-linearity and high-power CMOS structure according to claim 3, wherein the hetero-structural CMOS component is based on the conventional CMOS component to improve the characteristics of conventional CMOS of which the structure is modified.

13. A method of manufacturing a high-linearity and high-power CMOS, comprising the steps of:
using a Si bulk as a base on which a gate is structured;
arranging a source and a drain in the base between the two sides of the gate;
arranging a gate dielectric layer between the gate and the base;
providing a metallic silicide layer above the source, the drain, and the gate;
having the gate, the source, and the drain covered with the dielectric layer; and
forming the field plate on the dielectric layer, opposite to the top of gate and drain.

14. The method of manufacturing the high-linearity and high-power CMOS according to claim 13, wherein the gate dielectric layer is made of silica.

15. The method of manufacturing the high-linearity and high-power CMOS according to claim 13, wherein transistors formed with the gate, the source, and the drain that are arranged under the dielectric layer are a PMOS transistor and a NMOS transistor.
